(19) United States
(12) Patent Application Publication
(10) Pub. No.: US 2014/0038484 A1
(43) Pub. Date: Feb. 6, 2014

(54) COMPOSITE MATERIAL COMPRISING A LAYER OF POLYMERIC PIEZOELECTRIC MATERIAL MATCHED WITH A TEXTILE SUBSTRATE AND METHOD FOR MAKING SUCH A COMPOSITE MATERIAL

(71) Applicant: Giuseppe Pezzini, Bergamo (IT)

(72) Inventor: Giuseppe Pezzini, Bergamo (IT)

(21) Appl. No.: 14/110,127

(22) PCT Filed: Sep. 4, 2012
(86) PCT No.: PCT/IB2012/001707

§ 371 Date: Oct. 4, 2013

(30) Foreign Application Priority Data
Sep. 7, 2011 (IT) RM2011A000461

(51) Int. Cl. H01L 41/193; H01L 41/37

(52) U.S. Cl. CPC H01L 41/193; H01L 41/37
USPC 442/110; 156/60; 427/100; 156/272.6; 427/535

(57) ABSTRACT

A composite material is described. The composite material has a layer of polymeric piezoelectric material, where such polymeric piezoelectric layer has a first surface and a second surface, a textile substrate, and a first electrode disposed on the first surface of the polymeric piezoelectric layer. Conductors are provided on a surface of the textile substrate turned towards the second surface of the layer of polymeric piezoelectric material.

The present invention relates to a process for the realization of a composite material comprising a layer of polymeric piezoelectric material matched with a textile substrate.

In particular, said layer of polymeric piezoelectric material is deformed in the form of oriented and polarized film so as to provide the requested capacities to the textile substrate on which it is matched. In other words, said layer can transform a vibration or a deformation into an electrical signal, or vice versa, i.e. exposed to an electric signal said layer can generate a deformation or vibration, acting as an electromechanical transducer, a sensor or as an actuator.

The textile substrate confers resistance to the layer of polymeric piezoelectric material, as well as directional mechanical response in a manner which depends on the effort's direction.

Currently, one composite piezoelectric material is known, and the process for its realization is described in the patent application EP 0025751.

The composite material is obtained by soaking fabric in a polymer. In particular, the composite material, capable to show piezoelectric properties for induction of an electrical anisotropy as a result of an appropriate treatment, is equipped with at least one layer of a fabric soaked with polymer in at least one of its regions.

However, the composite material has some limits.

A first limit is given by the reduced piezoelectric capacities, which do not fully exploit the material's potential because the process of polarization, which provides a deformation contextual to the application of an electric field, is limited by the properties of the fabric that is already integrated with the polymer.

Another limit is given by the limited overall capacity of deformation of the composite material, which is due to the structure of the weft-warp fabric.

The process for the realization of such a composite material includes a phase of soaking of at least one layer of fabric by means of a polymer, followed by a phase of polarization. The step of soaking is carried out by the immersion of a fabric in a bath of polymer, molten or in solution.

The polarization phase is made by exposing the composite material to the simultaneous application of a mechanical deformation and of an electric field, plasma or corona.

However, this procedure presents some disadvantages.

One drawback is the complexity of the phase of polarization which is based on plasma or corona fields, or on the application of external electrostatic fields on the composite material, in order to initiate the piezoelectric behavior of the polymer. This complexity is due to the fact that not only the polymer is treated, but also the fabric within the matrix, and this alters the mechanical performance and inhibits the free deformation of the polymer.

Another composite material is described in patent application EP 2159857. This composite material behaves as an electromechanical transducer and comprises two layers of polymer in the form of films, and a layer of non-woven fabric interposed between them. The layers of polymer in the form of films are made by a non-fluorinated polymer or a mix of multiple non-fluorinated polymers.

However, one disadvantage of this composite material is that the intermediate layer of non-woven fabric can't guarantee the directionality and the dimensional resistance of an orthogonal fabric, nor the elasticity and the return of a knitted fabric.

The process for the realization of said composite material comprises the following phases:
A) providing for two polymer films,
B) annealing the polymer films,
C) providing a layer of fiber,
D) putting the fiber layer on the polymer films,
E) putting another layer of polymer film on the disposition fiber layer-polymer film,
F) combining the polymer film to the layer of fiber using high pressure or high temperature,
G) charging the disposition polymer film-fiber layer.

However, a disadvantage of this process is given by the fact that the two layers of active polymer are polarized after that their union with the intermediate layer and the junction with the electrodes has occurred. This fact, together with minor mechanical performances of the non-woven fabrics, strongly limits the performance of both the polarization process and the product.

The purpose of the present invention is to overcome these disadvantages, by providing a composite material, comprising a polymeric piezoelectric layer coupled with a layer of textile material, able to behave as an electromechanical transducer, transforming a pressure or a movement in an electrical signal, or vice versa as an actuator, transforming an electrical signal in a movement or a deformation.

In a profitable way, said composite material offers enhanced performances in ferroelectric, piezoelectric, dielectric or pyroelectric fields, in the sense that the piezoelectric properties of the composite material are able to facilitate the capacity of deformation and elastic return of a textile material (orthogonal or orthogonal mesh), in combination with the characteristics of the polarized piezoelectric polymer, without the mechanical restrictions given by the fact of being already connected to a textile substrate.

A further purpose of the present invention is a method for manufacturing said composite material.

Object of the invention is therefore a composite material comprising a layer of polymeric piezoelectric material, where said polymeric piezoelectric layer has a first surface and a second surface, opposite to the first surface, a textile substrate, a first electrode disposed on the first surface of the polymeric piezoelectric layer (2), where, on the surface of said textile substrate (3) facing said second surface of the layer of polymeric piezoelectric material, conductors are provided.

In a first option, said conductors might be constituted by a second electrode, which is disposed between the second surface of the piezoelectric layer and the textile substrate.

In a second option, said conductors, or only the surface thereof might be constituted by the material with which said textile substrate is realized. In particular, the material is an inherently conductive fabric and includes totally or at least partially metallic fibers and yarns of metal and/or carbon and/or conductive polymeric material.

In the case where the composite material provides for two electrodes, each electrode might be an electrically conductive layer made of a metal or with an electrically conductive polymer.

It is preferable that the material of the piezoelectric polymeric layer is chemically based on a fluorinated polymer.

It is preferable that the thickness of the piezoelectric polymeric layer is comprised between 10 and 2000 microns.

According to the invention, the textile substrate may be realized with a natural, artificial or synthetic material and may include conductive fibers in a percentage from 2% to 30%. These conductive fibers shall be metallic or realized with an electrically conductive or carbon polymer.

Advantageously, the composite material may further comprise a protective layer positioned on the first electrode in order to protect the composite material from water, atmospheric agents, or chemical agents aggressive for the composite material itself.

A further object of the invention is the realization proceeding of a composite material, comprising the following steps:
A) realizing a layer of polymeric piezoelectric material, having a first surface and a second surface, opposite said first surface,
B) polarizing the above mentioned polymeric piezoelectric layer,
C) applying a first electrode on the first surface of said polymeric piezoelectric layer,
D) applying conductors on the surface of a textile substrate turned towards said second surface of the layer of polymeric piezoelectric material,
E) matching said polymeric piezoelectric layer with the textile layer.

According to the invention, when said first electrode is an electrically conductive layer realized with an electrically conducting polymer, it is put down by means of the rolling or spreading or lamination of an electric conductive polymer, or by means of the PVD or CVD laying technique or by means of other laying techniques.

Furthermore, according to the invention, when said conductors are constituted by a second electrode, and this electrode is an electric conductive layer realized with an electrically conductive polymer, it is put down by means of the rolling or spreading or lamination of an electric conductive polymer, or by means of the PVD or CVD laying technique or by means of other laying techniques.

It is preferable that the matching of said polymeric piezoelectric layer with said textile substrate is realized by means of a simultaneous application of heat and pressure in a direction perpendicular to the matched surfaces of the layers.

Strategically, prior to step E), it is possible to provide for a phase of treatment of the second surface of the polymeric piezoelectric layer, in order to favor the adherence of said polymeric piezoelectric layer to the textile substrate and/or a phase of treatment of the first surface of the textile substrate in order to favor the adherence of said textile substrate to the polymeric piezoelectric layer. Each phase of treatment can be realized by means of a process for surface activation, such as a corona surface treatment, or plasma, or chemical activation treatment, or deposit of primer support.

Another possible advantage is to provide for, prior to step D) or simultaneously to said step D), or after step E), the following phase:
F) covering said first electrode with a protective layer.

The present invention will now be described, in an explanatory but not limitative way, according to a realization thereof, with particular reference to the figures attached, in which:

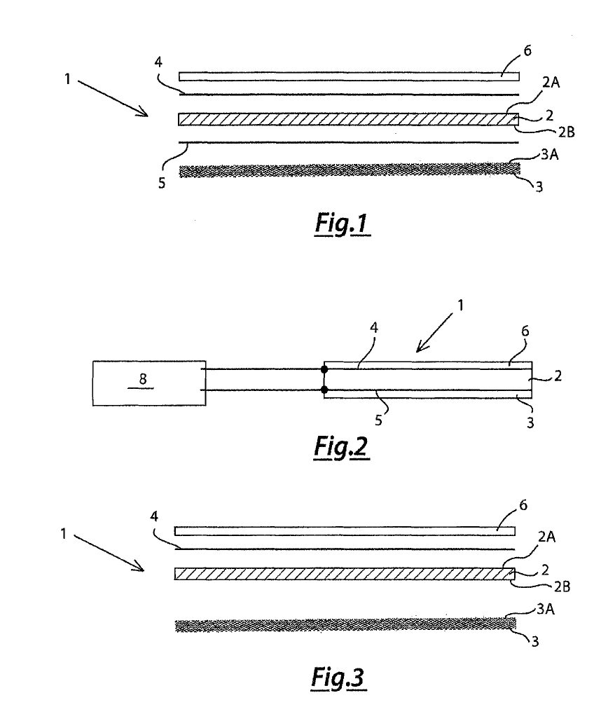

FIG. 1 is an exploded view of a first realization of the composite material according to the invention;

FIG. 2 shows schematically the composite material connected to an electrical circuit,

FIG. 3 is an exploded view of a second realization of the composite material according to the invention.

With reference to FIG. 1, it provides for a composite material 1 comprising a layer of a piezoelectric polymeric material 2 and a textile substrate 3, together with two electrodes, a first electrode 4 located on the piezoelectric polymeric layer 2 and a second electrode 5 placed between the piezoelectric polymer layer 2 and the textile substrate 3.

In particular, the piezoelectric polymeric layer presents a first surface 2A intended to come into contact with the first electrode 4, and a second surface 2B, opposite to said first surface, intended to come into contact with the second electrode 5. The textile substrate 3, in turn, has a first surface 3A intended to come into contact with the second electrode 5. The first electrode 4 is in contact with the first surface 2A of the piezoelectric layer 2, while the second electrode 5 is in contact both with the second surface 2B of the polymeric piezoelectric layer and with the first surface 3A of the textile substrate.

In the first realization form here described, each of said electrodes 4 and 5 is constituted by an electrically conductive layer which can be realized with a metal or with an electrically conductive polymer. In particular, in case of a metal electrode, it may be put down by PVD laying technique (Physical Vapour Deposition) or CVD laying technique (Chemical Vapour Deposition) or other laying techniques, while in case of an electrically conductive polymeric electrode, it may be put down by rolling or spreading of an electrically conductive polymer, in its molten form or in solution.

With reference to the electrically conductive layer which constitutes the second electrode 5, this layer might be a continuous layer or might be constituted in the form of a grid.

In the described realization, the second electrode 5 is put down on the second surface 2B of the piezoelectric polymeric layer 2, in the same way in which the first electrode 4 is put down on the first surface 2A of the same piezoelectric polymeric layer 2.

According to the invention, the second surface 2B of the piezoelectric polymeric layer 2 is functionalized in order to adhere with the textile substrate 3, favoring the action of the hot-pressing, or in order to favor another way of matching the piezoelectric polymeric layer 2 with the textile substrate 3.

The functionalization of the second surface 2B can be referred to an increased surface activity by chemical or physical modification of the first surface 2A of the piezoelectric polymeric layer, a higher adhesiveness, hydrophilicity or hydrophobicity. Such functionalization can be conferred by a process for surface activation, which might be a physical process (plasma, laser, corona, PVD, etc.) or a chemical activation treatment, (treatment with acid, alkali, metallization, CVD, etc.).

According to the invention, the polymer-based piezoelectric material is chemically based on a fluorinated polymer.

The polymer-based piezoelectric material presents better characteristics compared to materials with similar piezoelectric capacities, ceramic-based materials or material based on Polyvinylidene fluoride (PVDF).

In particular, the piezoelectric material can have a high range of response in dynamic frequency, for example between 1 and 1000 Hz, and with reference to mechanical properties, it may have a modulus of elasticity comprised among 1000 and 2000 MPa, an elastic elongation among 2% and 18%, and an elongation to break among 10% and 500%.

Therefore, its mechanical properties are superior with respect to a corresponding PVDF material.

The energy density is comprised between 10 and 50 mJ/cm3.

The range of voltage that leads to the implementation is also broad. Such range is variable depending on the resistance of the piezoelectric material, from the order of 10 to 100 volts and more.

The polymer-based piezoelectric material has a high electrical resistance, on the order of 10¹⁴ Ohm m, and a breakdown voltage on the order of 10⁷ V/mm, a high dielectric constant (between 5 and 100 at ambient temperature) and a high induced polarizability on the order of 0.1 C/m2.

The thickness of the polymeric layer is comprised among 10 and 2000 microns. Such a thickness allows to obtain a better matching between the piezoelectric polymeric layer 2 and the textile substrate 3, in function of the resistance and of the final product, as well as an adequate energy conversion, in function of the extent of deformation, of its frequency and thickness, the latter in turn connected to the volume of polymeric material per unit of surface.

As shown in FIG. 1, the textile substrate 3 has a first surface 3A which is in contact with the second electrode 5.

Said textile substrate provides the piezoelectric polymeric material 2 with a resistance and a mechanical directional response dependent on the application direction of the strain fields.

Specific capabilities and levels of mechanical response can be obtained applying different textile structures: orthogonal, twill, knitted crochet, warp or weft structures, with a different degree of closure and number of yarns per cm variable from 2 to 30, or using designs that encourage auxectic behaviors.

The main function of the textile substrate 3 is to direct the extent of deformation and the directionality, allowing the molding of products that optimally respond to external impulsions (sensors and actuators).

The textile substrate 3 imparts to the composite material dimensional stability and control of the deformation.

In particular, the textile substrate 3 can be characterized by one of the following properties:
a. be realized in simple orthogonal flat woven, with mechanical properties of deformation and resistance equal to each warp and weft,
b. be realized of flat woven having different elastic properties between warp and weft, capable of directing the deformation and the electrostatic reaction in an anisotropic way,
c. be made of a knitted fabric (so-called warp-knit construction or weft-knit) to allow higher deformations compared to a flat woven (anisotropy of the material),
d. having a density ranging between 2 and 30 yarns/cm in the directions of the warp and weft.

In the first realization being described, the composite material 1 also provides for a protective layer 6, positioned on the first electrode 4, to protect the composite material from water, atmospheric agents, or chemical agents aggressive for the composite material itself.

It is preferable that the protective layer 6 is also provided with a good abrasion and cut resistance.

With reference to FIG. 2, the polymeric piezoelectric material 2 is connected, through the electrodes 4 and 5, to an external electrical circuit 8, intended to collect the generated electrical signal (in case of use as a sensor) or the energy produced (in case of use as an actuator), or to transmit an electrical signal to the composite material 1 (in the case of use as an actuator).

The process for making the composite material 1 comprises the following phases:
A) realizing a layer of polymeric piezoelectric material 2, having a first surface 2A and a second surface 2B, opposite said first surface,
B) polarizing the above mentioned polymeric piezoelectric layer 2,
C) applying a first electrode 4 on the first surface 2A of said polymeric piezoelectric layer 2,
D) applying a second electrode 5 between the second surface 2B of the piezoelectric polymeric layer 2 and a first surface 3A of a textile substrate 3,
E) matching said polymeric piezoelectric layer 2 with the textile substrate 3.

With reference to the step of matching the piezoelectric polymeric layer 2 to the textile substrate 3 (step E), this matching is realized by means of a simultaneous application of heat and pressure in a direction perpendicular to the matched surfaces of the layers.

The operating conditions (temperature, pressure and time of application of the pressure) shall not exercise any influence on the status of the polymer, in particular on its polarization. Therefore, specific critical temperatures and pressures, relevant for each variation of the different materials, must not be exceeded. In particular, the matching can be achieved by flat pressing (better for the production of small parts, made of patterns and specific cutting) or rolling (better for the production of elements of greater length, which can then be rolled up).

According to the invention, before the matching step (step E), it is possible to provide for a treatment phase of the second surface of the piezoelectric polymeric layer 2, in order to favor the adherence of said piezoelectric polymeric layer 2 to the textile substrate 3 and/or a treatment phase of the first surface 3A of the textile substrate 3 in order to favor the adherence of the textile substrate to the piezoelectric polymeric layer 2, with the aim to steady the matching between the piezoelectric polymeric layer 2 and the textile substrate 3.

Both for the treatment of the second surface of the piezoelectric polymeric layer 2 and of the first surface of the textile substrate 3, it is possible to use a process of surface activation, such as a corona surface treatment, or plasma, or chemical activation treatment, or deposit of primer support.

According to the invention, it is possible to provide for, prior to step D) or simultaneously to said step D), or after step E), the following phase:
F) covering said first electrode 4 with a protective layer 6.

In a second realization shown in FIG. 3, the second electrode is constituted by the fabric of the textile substrate 3, which is an inherently conductive fabric and includes totally or at least partially metallic fibers and yarns of metal and/or carbon and/or conductive polymeric material.

The presence of metallic fibers and yarns of metal and/or carbon and/or conductive polymeric material in the textile substrate 3 allows the fabric of the same textile substrate 3 to replace the second electrode.

In particular, the presence of conductive fibers (metallic, or made with an electrically conductive polymer or with carbon) in the textile substrate 3, in a percentage among 2% and 30%, gives to the textile substrate itself the ability to collect the electrical charge generated by the piezoelectric polymeric material 2 and to convey said electrical charge to an external electrical circuit, as if the textile substrate 3 was a distributed electrode.

Advantageously, the structure of the composite material of said second realization form is simpler than that of the composite material of the first realization.

Where the fabric of the textile substrate 3 is inherently conductive, the method to produce the composite material does not provide the phase D. Therefore, from step C), referred to the application of a first electrode 4 to the first surface 2A of the piezoelectric polymeric layer 2, one can proceed directly with step E) regarding the matching of the piezoelectric polymeric layer 2 with the textile substrate 3.

However, according to the invention, the textile substrate 3 can be made with any material, natural, artificial or synthetic, depending on the final application. The choice of such material represents a further degree of freedom, which allows to implement the piezoelectric polymeric material 2 in different applications.

Natural materials offer a good compatibility with the skin for wearable applications in direct contact with the epidermis, and still have good mechanical characteristics. Synthetic materials can favor the adherence of the piezoelectric material, and find a greater chance of implementation for technical applications. Technical materials may also find application in protective elements (aramidic fiber fabrics, Nomex, para-aramidic, kevlar etc.).

The possibility of using coated or laminated fabrics allows further applications, facilitating the adherence of the two layers and expanding the types of materials and fields of use. A coated or laminated surface also enables an electrical conductivity functionalization of the surface through surface electrical charges, pigments or conductive elements included in the coating formulation. The obtained result combines the transfer of the electric charge with a better adherence of the two layers.

Advantageously, the benefits of the composite material object of the invention are related with the control and stabilization of form and methods of the deformation that the textile substrate is able to provide to the material, controlling its extent of expansion and increasing its duration.

Another advantage is that the coupling between the piezoelectric material and the textile substrate does not change the piezoelectric capacities of the polymeric material and does not interact with said polymeric material in an uncontrolled manner.

A further advantage is given by the possibility of introducing the composite material, object of the present invention, directly into a textile and packaging process. The result of the production is a material that can have the form, the texture and the quality properties determinable to the touch just as a textile product.

Hence the possibility of profitably applying the composite material object of the invention as an active element integrated into textiles and clothing products, in the footwear or architecture industry, and in other areas for which it is possible to use the material's capacity to react in an electric way to mechanical inputs.

The present invention has been described, for explanatory but not limitative purposes, according to its preferred realizations, but it is to be understood that variations and/or modifications thereof can be made by experts without departing from the scope of protection, as defined by the enclosed claims.

1. A composite material comprising:
a layer of polymeric piezoelectric material, where such polymeric piezoelectric layer has a first surface and a second surface, the second surface being opposite to the first surface,
a textile substrate, and
a first electrode disposed on the first surface of the polymeric piezoelectric layer, wherein conductors are provided on a surface of said textile substrate turned towards the second surface of the layer of polymeric piezoelectric material.

2. The composite material according to claim 1, wherein the conductors comprise a second electrode placed between the second surface of the piezoelectric layer and the textile substrate.

3. The composite material according to claim 1, wherein the conductors are made by a same material of which the textile substrate or only the surface of the textile substrate is made, the material being an inherently conductive fabric, the fabric comprising entirely or at least partially metallic fibres and yarns in metal and/or in carbon and/or in polymeric conductive material.

4. The composite material according to claim 1, wherein each of the first and second electrodes is an electric conductive layer realized by a metal or by an electrically conductive polymer.

5. The composite material according to claim 1, wherein a material of the piezoelectric polymeric layer is chemically based on a fluoridated polymer.

6. The composite material according to claim 1, wherein a thickness of the piezoelectric polymeric layer is comprised between 10 micron and 2000 micron.

7. The composite material according to claim 1, wherein the textile substrate is realized with a natural, artificial or synthetic material.

8. The composite material according to claim 1, wherein the textile substrate comprises conductive fibres in a percentage from 2% to 30%; said conductive fibres being metallic or realized with an electrical conductive or carbon polymer.

9. The composite material according to claim 1, further comprising a protective layer positioned on the first electrode, in order to protect the composite material from water, atmospheric agents, or chemical agents aggressive for the composite material itself.

10. A method for realizing the composite material according to claim 1, comprising the steps of:
A) realizing a layer of polymeric piezoelectric material, having the first surface and a second surface, the second surface being opposite to said first surface,
B) polarizing the layer of polymeric piezoelectric material,
C) applying the first electrode on the first surface of said layer of polymeric piezoelectric material,
D) applying conductors on the surface of the textile substrate turned towards said second surface of the layer of polymeric piezoelectric material, and
E) matching said layer of polymeric piezoelectric material with the textile substrate.

11. The method according to claim 10, wherein said first electrode is an electric conductive layer realized with an electric conductive polymer, and is deposited by means of rolling, or spreading or lamination of an electric conductive polymer, by means of a Physical Vapor Deposition (PVD) or a Chemical Vapor Deposition (CVD) laying technique or by means of other laying techniques.

12. The method according to claim 10, wherein said conductors comprise a second electrode, said second electrode being an electric conductive layer realized with an electric conductive polymer, and being deposited by means of rolling, or spreading or lamination of an electric conductive polymer, by means of a PVD or a CVD laying technique or by means of other laying techniques.

13. The method according to claim 10, wherein a phase of matching said polymeric piezoelectric layer with said textile substrate is realized by means of a simultaneous application of heat and pressure in a direction perpendicular to the matched surfaces of the polymeric piezoelectric and textile substrate layers.

14. The method according to claim 10, wherein, before step E), a step of treatment of the second surface of the layer of polymeric piezoelectric material is provided for, in order to promote an adherence of said polymeric piezoelectric layer to the textile substrate and/or a step of treatment of the first surface of the textile substrate in order to promote the adherence of said textile substrate to the polymeric piezoelectric layer; each step of treatment being realized by means of a process for surface activation, such as a corona surface treatment, plasma, chemical activation treatment, or deposit of primer support.

15. The method according to claim 10, further comprising before step D) or simultaneously to step D), or after step E), the following step:
F) covering said first electrode with a protective layer.
